(19) United States
(12) Patent Application Publication
(10) Pub. No.: US 2026/0246343 A1
(43) Pub. Date: Aug. 20, 2026

(54) ELECTRIC COMPRESSOR

(71) Applicant: SANDEN CORPORATION, Isesaki-shi, Gunma (JP)

(72) Inventor: Mikio KOBAYASHI, Isesaki-shi, Gunma (JP)

(21) Appl. No.: 19/164,571

(22) PCT Filed: May 22, 2024
(86) PCT No.: PCT/JP2024/018815

§ 371 Date: Sep. 11, 2025

(30) Foreign Application Priority Data
Jun. 22, 2023 (JP) 2023-102293

(51) Int. Cl. H02K 11/00; H02K 5/04; H02K 11/33; H05K 7/14

(52) U.S. Cl. CPC H02K 11/0094; H02K 5/04; H02K 11/33; H05K 7/1427

(57) ABSTRACT

In an electric compressor (1), a filter circuit portion (30) includes a first filter circuit board (31) on which a plurality of electrolytic capacitors (51) is mounted, a second filter circuit board (33) on which a normal mode choke coil (53), a common mode choke coil (55) and the like are mounted, and a bus bar member (35) having a bus bar (351) that electrically connects the first filter circuit board (31) and the second filter circuit board (33), and a resin holding portion (352) that holds the bus bar (351), and the first filter circuit board (31) and the second filter circuit board (33) are accommodated in an inverter accommodating portion (7) in a state of being placed on top of each other across the bus bar member (35).

### TECHNICAL FIELD

The present invention relates to an electric compressor.

### BACKGROUND ART

One example of an electric compressor is described in Patent Literature 1. The electric compressor described in Patent Literature 1 is an inverter-integrated electric compressor used in a vehicle air-conditioning apparatus. The electric compressor described in Patent Literature 1 includes a housing in which a motor has been integrated, an inverter for driving the motor, an inverter accommodating portion provided in the housing, and a cover that closes the inverter accommodating portion.

The inverter includes six power switching elements for converting direct current power into three-phase alternating current power, an inverter control board on which a control circuit that controls the six power switching elements is mounted, and a filter circuit board on which, for example, a coil and a capacitor, which are filter components, are mounted. They are accommodated in the inverter accommodating portion.

### CITATION LIST

### Patent Literature

Patent Literature 1: JP-A-2020-143594

### SUMMARY OF INVENTION

### Problems to be Solved by Invention

In recent years, due to, for example, the advancement of electronic control units accompanying motorization of automobiles, electromagnetic noise suppression has been further required also in electric compressors used in vehicle air-conditioning apparatuses. As one of measures of such electromagnetic noise suppression, it is conceivable to, for example, adopt a coil having a larger inductance value than before. However, a coil having a large inductance value has a large component size. Therefore, simply adopting a coil having a large inductance value leads to an increase in the projected area of the filter circuit board, and by extension an increase in the projected area of the inverter accommodating portion that accommodates the filter circuit board. If the projected area of the inverter accommodating portion increases, the place where the electric compressor is installed may be limited, and the cover that closes the inverter accommodating portion may be easily affected by vibration, and the noise caused by the vibration of the cover may increase, which is not desirable.

Hence, an object of the present invention is to provide an electric compressor capable of suppressing an increase in a projected area of an inverter accommodating portion even if a filter component for electromagnetic noise suppression increases in size or the number of filter components increases.

### Solution to Problems

According to one aspect of the present invention, an electric compressor is provided. The electric compressor provided includes: a housing configured to accommodate a motor that rotates a rotary shaft and a compression mechanism that is driven by rotation of the rotary shaft; an inverter accommodating portion that is provided integrally with the housing, includes an opening portion, and is configured to accommodate an inverter that drives the motor; and a cover member configured to close the opening portion of the inverter accommodating portion. The inverter includes an inverter circuit portion that supplies power to the motor, and a filter circuit portion for reducing electromagnetic noise. The filter circuit portion includes a first filter circuit board on which at least one first filter component is mounted, a second filter circuit board on which at least one second filter component is mounted, and a bus bar member having a bus bar that electrically connects the first filter circuit board and the second filter circuit board, and a resin holding portion that holds the bus bar. The first filter circuit board, the second filter circuit board, the bus bar member are accommodated in the inverter accommodating portion in a state where the first filter circuit board and the second filter circuit board are placed on top of each other across the bus bar member.

### Effects of Invention

According to the present invention, it is possible to provide an electric compressor capable of suppressing an increase in a projected area of an inverter accommodating portion even if a filter component for electromagnetic noise suppression increases in size or the number of filter components increases.

### BRIEF DESCRIPTION OF DRAWINGS

FIG. 1 is a schematic vertical cross-sectional view of an electric compressor according to an embodiment.

FIG. 2 is a schematic perspective view illustrating an inverter and an inverter accommodating portion.

FIG. 3 is a perspective view of a filter circuit portion configuring the inverter.

FIG. 4 is an exploded perspective view of the filter circuit portion.

FIG. 5 is a partially enlarged cross-sectional view of a bus bar member.

FIG. 6 is a perspective view illustrating a modification of the bus bar member.

FIG. 7 is a perspective view illustrating a modification of the filter circuit portion.

### DESCRIPTION OF EMBODIMENTS

An embodiment of the present invention is described hereinafter with reference to the accompanying drawings. Note that the following terms such as “first”, “second”, . . . are simply used to distinguish similar elements, and do not, for example, limit elements to which the terms are assigned.

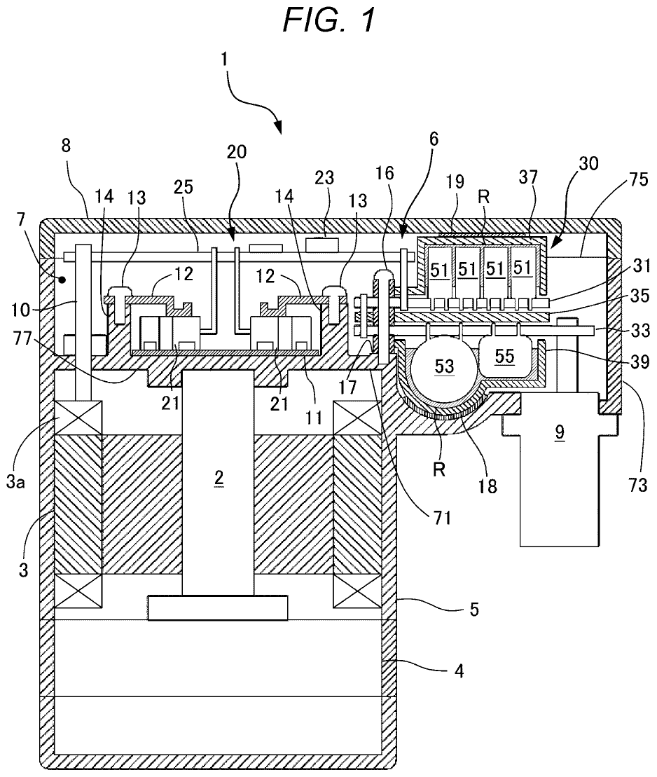

FIG. 1 is a schematic vertical cross-sectional view of an electric compressor 1 according to one embodiment of the present invention. The electric compressor 1 according to the embodiment is an inverter-integrated electric compressor integrally including an inverter. The electric compressor 1 is used for a vehicle air-conditioning apparatus. In other words, the electric compressor 1 is mounted on a vehicle to configure a part of a refrigerant circuit of the vehicle air-conditioning apparatus, and is configured in such a manner as to compress and discharge a refrigerant.

The electric compressor 1 includes a rotary shaft 2, a motor 3, a compression mechanism 4, a housing 5, an inverter 6, an inverter accommodating portion 7, and a cover member 8.

The rotary shaft 2 is supported by a bearing of which the illustration is omitted in such a manner as to be rotatable relative to the housing 5. The motor 3 is a three-phase synchronous motor (brushless DC motor), is driven by power supplied, and rotates the rotary shaft 2. The compression mechanism 4 is, for example, a scroll compression mechanism, and is driven by the rotation of the rotary shaft 2. The housing 5 has a cylindrical cross section and accommodates the rotary shaft 2, the motor 3, and the compression mechanism 4. In the housing 5, the motor 3 and the compression mechanism 4 are placed in series in an axial direction of the rotary shaft 2.

The inverter 6 supplies power to the motor 3 to drive the motor 3. The inverter 6 includes an inverter circuit portion 20 that supplies power to the motor 3, and a filter circuit portion 30 for reducing electromagnetic noise. The inverter accommodating portion 7 is provided integrally with the housing 5, and accommodates the inverter 6. Specifically, the inverter accommodating portion 7 is provided at an end portion on a motor 3 side of the housing 5. In the embodiment, the inverter accommodating portion 7 has a larger projected area than the housing 5. The inverter accommodating portion 7 is formed with a bottom wall 71 and a peripheral wall 73 erected at a peripheral edge of the bottom wall 71, and includes an opening portion 75 that faces the bottom wall 71. In addition, the inverter circuit portion 20 and the filter circuit portion 30, which configure the inverter 6, are accommodated in the inverter accommodating portion 7, and the opening portion 75 of the inverter accommodating portion 7 is closed with the cover member 8. The cover member 8 is fixed to a peripheral wall (which is also a part of the housing 5.) of the inverter accommodating portion 7 with a bolt of which the illustration is omitted.

An HV connector (high voltage connector) 9 for supplying direct current power from a vehicle-mounted battery of which the illustration is omitted to the inverter 6 (the inverter circuit portion 20) is attached to the bottom wall 71 of the inverter accommodating portion 7. Moreover, a part of the bottom wall 71 of the inverter accommodating portion forms a partition wall 77 that separates the inside of the inverter accommodating portion 7 from the inside of the housing 5.

Note that although not illustrated in the drawing, the housing 5 is formed with an inlet through which the refrigerant flows into the housing 5 and an outlet through which the refrigerant flows out of the housing 5. In the embodiment, the inlet is configured in such a manner as to allow the refrigerant to flow into the housing 5 between the partition wall 77 and the motor 3. The refrigerant that has flowed into the housing 5 through the inlet reaches the compression mechanism 4 through the motor 3, and is compressed by the compression mechanism 4. The refrigerant that has been compressed by the compression mechanism 4 then flows out through the outlet.

The refrigerant that flows into the housing 5 through the inlet is a low-temperature gaseous refrigerant that has passed through an expansion valve and an evaporator in the refrigerant circuit of the vehicle air-conditioning apparatus. Therefore, the partition wall 77 and the motor 3 can be cooled by the refrigerant that flows into the housing 5 through the inlet.

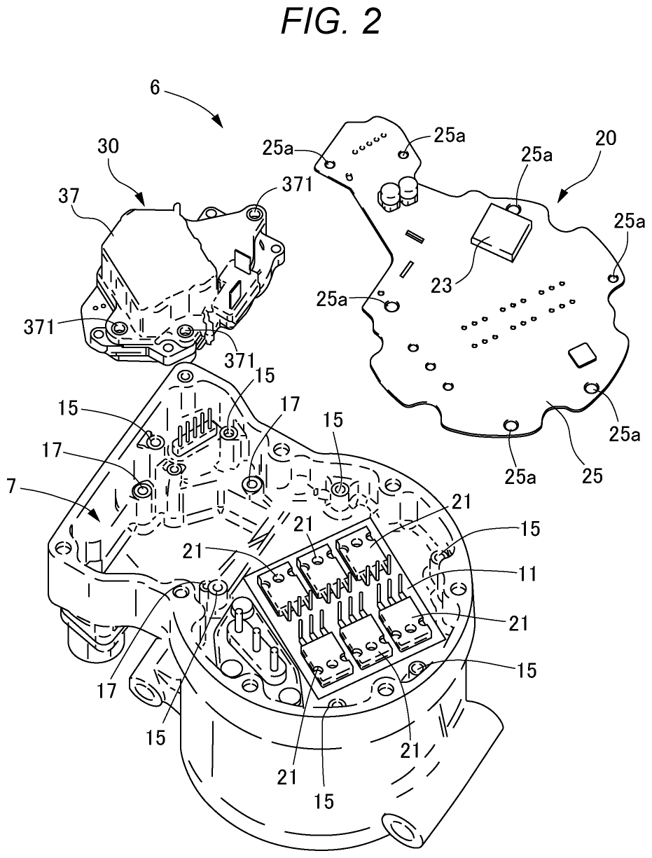

The inverter 6 is further described with reference to FIGS. 1 and 2. FIG. 2 is a schematic perspective view illustrating the inverter 6 and the inverter accommodating portion 7. As described above, in the embodiment, the inverter 6 includes the inverter circuit portion 20 that supplies power to the motor 3, and the filter circuit portion 30 for reducing electromagnetic noise.

The inverter circuit portion 20 is configured in such a manner as to convert direct current power to be supplied from the vehicle-mounted battery via the HV connector 9 into three-phase alternating current power and supply the three-phase alternating current power to (a stator coil 3a of) the motor 3 via a power supply line extending through the partition wall 77. Hence, the inverter circuit portion 20 includes six power switching elements 21, and an inverter control board 25 on which a control circuit 23 that controls the six power switching elements 21 is mounted.

In the embodiment, the six power switching elements 21 are placed on a sheet-like first heat dissipation member 11 installed on a surface on an inverter accommodating portion 7 side of the partition wall 77. Moreover, each of the six power switching elements 21 is fixed in a state of being pressed against the first heat dissipation member 11 by an arm member 12 (refer to FIG. 1). The arm member 12 is attached, with a bolt 13, to an arm attachment portion 14 provided in the inverter accommodating portion 7.

A plurality of (here, seven) mounting holes 25a is formed in the inverter control board 25. The inverter control board 25 is attached to a board attachment portion 15 provided in the inverter accommodating portion 7 with a plurality of bolts of which the illustrations are omitted. In the embodiment, the inverter control board 25 is placed near the cover member 8, that is, spaced away from the six power switching elements 21 (refer to FIG. 1). Hence, each of the six power switching elements 21 has a lead extending toward the inverter control board 25, more specifically, a lead extending through the inverter control board 25. In addition, these leads are soldered to the inverter control board 25. As a result, the six power switching elements 21 are electrically connected to the inverter control board 25.

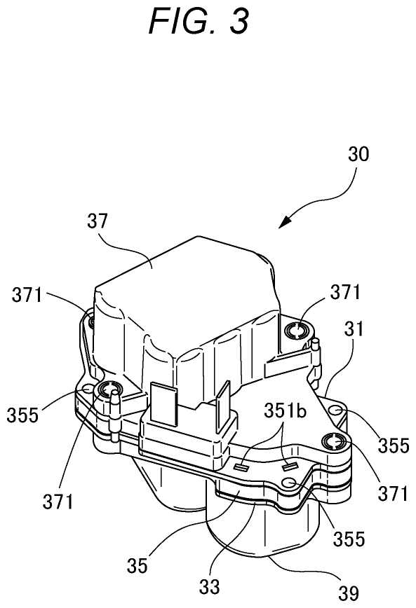

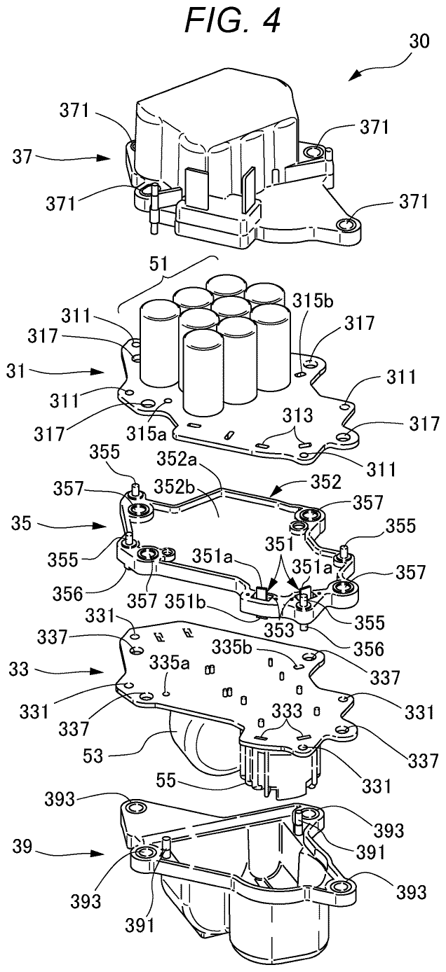

The filter circuit portion 30 is placed between the inverter circuit portion 20 and the HV connector 9. FIG. 3 is a perspective view of the filter circuit portion 30, and FIG. 4 is an exploded perspective view of the filter circuit portion 30.

In the embodiment, the filter circuit portion 30 includes a first filter circuit board 31, a second filter circuit board 33, and a bus bar member 35.

At least one filter component (hereinafter referred to as the “first filter component”.) for electromagnetic noise suppression is mounted on one surface of the first filter circuit board 31. The at least one first filter component mounted on the one surface of the first filter circuit board 31 is a relatively large filter component. The at least one first filter component may include a plurality of filter components of the same type or different types. Although not particularly limited, in the embodiment, a plurality of (here, nine) electrolytic capacitors 51 is mounted as the at least one first filter component on the one surface of the first filter circuit board. Note that the one surface of the first filter circuit board 31 is an upper surface in FIGS. 1 and 4, and is a surface facing the cover member 8 when accommodated in the inverter accommodating portion 7.

Here, although not illustrated in the drawings, a plurality of electronic components smaller than the at least one first filter component (here, the electrolytic capacitors 51) is also mounted on the first filter circuit board 31. At least a part of these small electronic components is mounted on the other surface (a lower surface in FIGS. 1 and 4, which is a surface facing the bottom side of the inverter accommodating portion 7 when accommodated in the inverter accommodating portion 7.) of the first filter circuit board 31, more specifically, at positions avoiding an area below the plurality of electrolytic capacitors 51 on the other surface of the first filter circuit board 31.

At least one filter component (hereinafter referred to as the “second filter component”.) for electromagnetic noise suppression is mounted on one surface of the second filter circuit board 33. The at least one second filter component mounted on the one surface of the second filter circuit board 33 is a relatively large filter component, as in the at least one first filter component, and may include a plurality of filter components of the same type or different types. Although not particularly limited, in the embodiment, a normal mode choke coil 53, a common mode choke coil 55, an X capacitor, and a Y capacitor are mounted as the at least one second filter component on the one surface of the second filter circuit board 33. However, the X capacitor and the Y capacitor are not illustrated in the drawings. Note that the one surface of the second filter circuit board 33 is a lower surface in FIGS. 1 and 4, and is a surface facing the bottom side of the inverter accommodating portion 7 when accommodated in the inverter accommodating portion 7.

Here, although not illustrated in the drawings, a plurality of electronic components smaller than the at least one second filter component (here, the normal mode choke coil 53, the common mode choke coil 55, the X capacitor, and the Y capacitor) is also mounted on the second filter circuit board 33. At least a part of these small electronic components are mounted on the other surface (an upper surface in FIGS. 1 and 4, which is a surface facing the cover member 8 when accommodated in the inverter accommodating portion 7.) of the second filter circuit board 33, more specifically, at positions avoiding an area above the normal mode choke coil 53, the common mode choke coil 55, the X capacitor, and the Y capacitor on the other surface of the second filter circuit board 33.

Note that the normal mode choke coil 53, the common mode choke coil 55, the X capacitor, and the Y capacitor as the at least one second filter component may be simply referred to below as “the normal mode choke coil 53, the common mode choke coil 55 and the like”

The bus bar member 35 as a whole is formed in a plate shape, and has an outer shape substantially corresponding to an outer shape of the first filter circuit board 31 and an outer shape of the second filter circuit board 33. The bus bar member 35 includes a pair of metal bus bars 351 and 351 for electrically connecting the first filter circuit board 31 and the second filter circuit board 33, and a resin holding portion 352 that holds the pair of bus bars 351 and 351. Although not particularly limited, in the embodiment, the bus bar member 35 is formed as a plate-shaped resin molded body in which the pair of bus bars 351 and 351 has been inserted.

In the embodiment, the holding portion 352 is formed in a plate shape having an approximately H-shaped cross section in which a peripheral edge portion 352a having a predetermined width is raised on both sides in its thickness direction relative to inner portions 352b, except the peripheral edge portion 352a. In other words, each of two surfaces of the holding portion 352, more specifically, each of two surfaces of the bus bar member 35 is formed with the inner portion 352b that is recessed relative to the peripheral edge portion 352a.

The pair of bus bars 351 and 351 is placed with a predetermined spacing therebetween in the peripheral edge portion 352a of the holding portion 352. Each of the pair of bus bars 351 and 351 includes a first protruding portion 351a protruding from the peripheral edge portion 352a of the holding portion 352 toward one side (an upper side in FIGS. 1 and 4) in the thickness direction, and a second protruding portion 351b protruding from the peripheral edge portion 352a of the holding portion 352 toward the other side (a lower side in FIGS. 1 and 4) in the thickness direction.

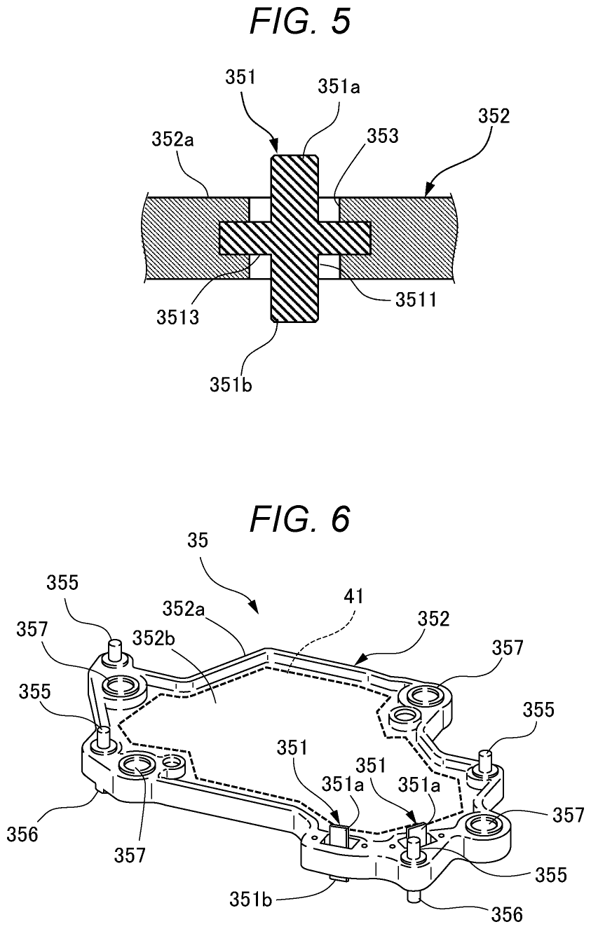

FIG. 5 is a partially enlarged cross-sectional view of the bus bar member 35, and illustrates the bus bar 351 and a surrounding portion thereof. The bus bar 351 is formed in a cross shape. The bus bar 351 includes a conductive portion 3511 for electrically connecting the first filter circuit board 31 and the second filter circuit board 33, the conductive portion 3511 extending through the peripheral edge portion 352a of the holding portion 352 in the thickness direction, and a held portion 3513 that extends, intersecting the conductive portion 3511, and is held by the holding portion 352. Note that the held portion 3513 may also be referred to as an insert portion. In addition, one end portion of the conductive portion 3511 forms the first protruding portion 351a, and the other end portion of the conductive portion 3511 forms the second protruding portion 351b.

More specifically, in the embodiment, a through-hole 353 penetrating in the thickness direction is formed in the peripheral edge portion 352a of the holding portion 352, and the bus bar 351 is placed in the through-hole 353. In addition, the conductive portion 3511 of the bus bar 351 extends in the axial direction in the through-hole 353, and has one end portion protruding as the first protruding portion 351a from one side of the through-hole 353, and the other end portion protruding as the second protruding portion 351b from the other side of the through-hole 353. The held portion 3513 extends in a direction orthogonal to the axial direction of the through-hole 353, and two end portions thereof are buried in a peripheral wall of the through-hole 353, that is, the holding portion 352. Consequently, the held portion 3513, and by extension the bus bar 351, is held by the holding portion 352.

In other words, in the embodiment, the bus bar 351 is placed in the through-hole 353 formed in the holding portion 352, only the two end portions of the held portion 3513 are buried in the holding portion 352 (that is, a resin portion), and the other portions are exposed from the holding portion 352. In particular, the conductive portion 3511 of the bus bar 351 is not in contact with the peripheral wall of the through-hole 353, that is, the holding portion 352.

In the embodiment, the first filter circuit board 31, the second filter circuit board 33, and the bus bar member 35 are accommodated in the inverter accommodating portion 7 in a state where the first filter circuit board 31 and the second filter circuit board 33 are placed on top of each other across the bus bar member 35. Specifically, the first filter circuit board 31, the second filter circuit board 33, and the bus bar member 35 are accommodated in the inverter accommodating portion 7 in a state where the other surface (the surface on which the electrolytic capacitors 51 are not mounted) of the first filter circuit board 31 and the other surface (the surface on which the normal mode choke coil 53, the common mode choke coil 55 and the like are not mounted) of the second filter circuit board 33 are placed in such a manner as to face each other across the bus bar member 35. The details are described below.

Firstly, the first filter circuit board 31 is attached to the bus bar member 35 in a state where the other surface on which the plurality of electrolytic capacitors 51 is not mounted is placed on one surface (an upper surface in FIGS. 1 and 4) of the bus bar member 35. Specifically, the first filter circuit board 31 is attached to the bus bar member 35 in a state where the other surface on which the plurality of electrolytic capacitors 51 is not mounted is placed on the peripheral edge portion 352a on one surface (an upper surface in FIGS. 1 and 4) side of the holding portion 352 of the bus bar member 35.

Here, the one surface of the bus bar member 35 is provided with a plurality of (here, four) resin first pin portions 355 protruding from the one surface. Specifically, the plurality of (four) first pin portions 355 is erected, spaced apart from one another in a circumferential direction, on the peripheral edge portion 352a on the one surface side of the holding portion 352 of the bus bar member 35. Moreover, a plurality of (the same number as the plurality of first pin portions 355, that is, four) first pin insertion holes 311 is formed in the vicinity of a peripheral edge portion of the first filter circuit board 31 in such a manner as to correspond to the plurality of first pin portions 355 of the bus bar member 35. When the first filter circuit board 31 is attached to the bus bar member 35, each of the plurality of first pin portions 355 of the bus bar member 35 is inserted through its corresponding first pin insertion hole 311 of the first filter circuit board 31, and then a distal end portion of the each of the plurality of first pin portions 355 of the bus bar member 35 is thermally staked. Consequently, the first filter circuit board 31 and the bus bar member 35 are aligned, and the first filter circuit board 31 is fixed to the one surface of the bus bar member 35.

Moreover, a pair of first bus bar insertion holes 313 and 313 corresponding to the pair of bus bars 351 and 351 of the bus bar member 35 is formed in the first filter circuit board 31. When the first filter circuit board 31 is attached to the bus bar member 35, the first protruding portions 351a of the pair of bus bars 351 and 351 of the bus bar member 35 are inserted through the pair of first bus bar insertion holes 313 and 313 of the first filter circuit board 31, and the first protruding portions 351a of the pair of bus bars 351 and 351 of the bus bar member 35 are soldered to the first filter circuit board 31. Consequently, the pair of bus bars 351 and 351 of the bus bar member 35 is electrically connected to the first filter circuit board 31.

Here, as described above, the first protruding portion 351a of each of the bus bars 351 is a part of the conductive portion 3511 of the bus bar 351, and most of the conductive portion 3511 of the bus bar 351 is located in the through-hole 353 and is not in contact with the holding portion 352 (the resin portion). Moreover, only the two end portions of the held portion 3513, which are located away from the first protruding portion 351a, are buried in the holding portion 352 in the bus bar 351. Hence, dissipation of heat that is produced when the first protruding portion 351a is soldered to the first filter circuit board 31 is suppressed, and soldering quality is stabilized. Moreover, the holding portion 352 is prevented from, for example, melting and deforming due to the heat that is produced when the first protruding portion 351a is soldered to the first filter circuit board 31.

The above-mentioned small electronic components mounted on the other surface of the first filter circuit board 31 are accommodated in the inner portion 352b on the one surface side of the holding portion 352 of the bus bar member 35.

Next, the second filter circuit board 33 is attached to the bus bar member 35 in a state where the other surface on which the normal mode choke coil 53, the common mode choke coil 55 and the like are not mounted is placed on the other surface (a lower surface in FIGS. 1 and 4) of the bus bar member 35. Specifically, the second filter circuit board 33 is attached to the bus bar member 35 in a state where the other surface on which the normal mode choke coil 53, the common mode choke coil 55 and the like are not mounted is placed on the peripheral edge portion 352a on the other surface (a lower surface in FIGS. 1 and 4) side of the holding portion 352 of the bus bar member 35.

Here, as in the one surface of the bus bar member 35, the other surface of the bus bar member 35 is provided with a plurality of (here, four) resin second pin portions 356 protruding from the other surface (however, only two of them are illustrated in FIG. 4.). Specifically, the plurality of (four) second pin portions 356 is erected, spaced apart from one another in the circumferential direction, on the peripheral edge portion 352a on the other surface side of the holding portion 352 of the bus bar member 35. Moreover, a plurality of (the same number as the plurality of second pin portions 356, that is, four) second pin insertion holes 331 is formed in the vicinity of a peripheral edge portion of the second filter circuit board 33 in such a manner as to correspond to the plurality of second pin portions 356 of the bus bar member 35. When the second filter circuit board 33 is attached to the bus bar member 35, each of the plurality of second pin portions 356 of the bus bar member 35 is inserted through its corresponding second pin insertion hole 331 of the second filter circuit board 33, and then a distal end portion of the each of the plurality of second pin portions 356 of the bus bar member 35 is thermally staked. Consequently, the second filter circuit board 33 and the bus bar member 35 are aligned, and the second filter circuit board 33 is fixed to the other surface of the bus bar member 35.

Moreover, a pair of second bus bar insertion holes 333 and 333 corresponding to the pair of bus bars 351 and 351 of the bus bar member 35 is formed in the second filter circuit board 33. When the second filter circuit board 33 is attached to the bus bar member 35, the second protruding portions 351b of the pair of bus bars 351 and 351 of the bus bar member 35 are inserted through the pair of second bus bar insertion holes 333 and 333 of the second filter circuit board 33, and the second protruding portions 351b of the pair of bus bars 351 and 351 are soldered to the second filter circuit board 33. Consequently, the pair of bus bars 351 and 351 of the bus bar member 35 is electrically connected to the second filter circuit board 33. More specifically, the first filter circuit board 31 and the second filter circuit board 33 are electrically connected via (the pair of bus bars 351 and 351 of) the bus bar member 35.

Here, as described above, the second protruding portion 351b of each of the bus bars 351 is a part of the conductive portion 3511 of the bus bar 351, and most of the conductive portion 3511 of the bus bar 351 is located in the through-hole 353 and is not in contact with the holding portion 352 (the resin portion). Moreover, only the two end portions of the held portion 3513, which are located away from the second protruding portion 351b, are buried in the holding portion 352 in the bus bar 351. Hence, dissipation of heat that is produced when the second protruding portion 351b is soldered to the second filter circuit board 33 is suppressed, and soldering quality is stabilized. Moreover, the holding portion 352 is prevented from, for example, melting and deforming due to the heat that is produced when the second protruding portion 351b is soldered to the second filter circuit board 33.

The above-mentioned small electronic components mounted on the other surface of the second filter circuit board 33 are accommodated in the inner portion 352b on the other surface side of the holding portion 352 of the bus bar member 35.

As described above, the first filter circuit board 31 and the second filter circuit board 33 are integrated together via the bus bar member 35, and the first filter circuit board 31 is electrically connected to the second filter circuit board 33.

In the embodiment, the filter circuit portion 30 further includes a first case member 37 and a second case member 39.

The first case member 37 is formed of, for example, a hard resin. The first case member 37 is configured in such a manner as to be attached to the one surface of the first filter circuit board 31 and accommodate the plurality of electrolytic capacitors 51 mounted on the one surface of the first filter circuit board 31.

In the embodiment, the first case member 37 is attached to the one surface of the first filter circuit board 31 as follows:

Firstly, a predetermined amount of resin R in a softened state or a molten state is filled in the first case member 37. Next, the first filter circuit board 31 and the first case member 37 are aligned, and the first case member 37 is attached to the one surface of the first filter circuit board 31. The first filter circuit board 31 and the first case member 37 are aligned by inserting two third pin portions (not illustrated in the drawing.) provided to the first case member 37 through a third pin insertion hole 315a and a first pin insertion long hole 315b, which are formed in the first filter circuit board 31. Thereafter, the resin R filled in the first case member 37 is cured. Consequently, the first case member 37 is fixed on the one surface of the first filter circuit board 31. Moreover, gaps in the first case member 37, that is, gaps between the electrolytic capacitors 51 and gaps between the electrolytic capacitors 51 and the first case member 37 are filled with the resin R. Note that it is preferable that a heat-resistant thermoplastic resin or a thermosetting resin be used as the resin R.

As in the first case member 37, the second case member 39 is formed of, for example, a hard resin. The second case member 39 is configured in such a manner as to be attached to the one surface of the second filter circuit board 33 and accommodate the normal mode choke coil 53 and the like mounted on the one surface of the second filter circuit board 33.

In the embodiment, as in the first case member 37, the second case member 39 is attached to the one surface of the second filter circuit board 33 as follows:

Firstly, a predetermined amount of the resin R in the softened state or the molten state is filled in the second case member 39. Next, the second filter circuit board 33 and the second case member 39 are aligned, and the second case member 39 is attached to the one surface of the second filter circuit board 33. The second filter circuit board 33 and the second case member 39 are aligned by inserting two fourth pin portions 391 provided to the second case member 39 through a fourth pin insertion hole 335a and a second pin insertion long hole 335b, which are formed in the second filter circuit board 33. Thereafter, the filled resin R is cured. Consequently, the second case member 39 is fixed on the one surface of the second filter circuit board 33. Moreover, gaps in the second case member 39, that is, gaps between components such as the normal mode choke coil 53 and the like and gaps between the normal mode choke coil 53 and the like and the second case member 39 are filled with the resin R.

In this manner, in addition to the first filter circuit board 31, the second filter circuit board 33, and the bus bar member 35, the first case member 37 and the second case member 39 are also integrated. In other words, in the embodiment, the filter circuit portion 30 includes the first filter circuit board 31, the second filter circuit board 33, the bus bar member 35, the first case member 37, and the second case member 39, which are integrated to form the filter circuit portion 30.

Such a filter circuit portion 30 is attached and fixed to a filter attachment portion 17 provided in the inverter accommodating portion 7, with a plurality of bolts 16 (only one of them is illustrated in FIG. 1.).

Specifically, in the embodiment, a plurality of (here, four) mounting holes is formed in each of the first filter circuit board 31, the second filter circuit board 33, the bus bar member 35, the first case member 37, and the second case member 39, corresponding to one another. In other words, four first mounting holes 317 are formed in the first filter circuit board 31, and four second mounting holes 337 are formed in the second filter circuit board 33. Moreover, four third mounting holes 357 are formed in the bus bar member 35, four fourth mounting holes 371 are formed in the first case member 37, and four fifth mounting holes 393 are formed in the second case member 39. Here, the third mounting holes 357, the fourth mounting holes 371, and the fifth mounting holes 393 may be formed by metal cylindrical sleeves inserted at the time of molding.

The filter circuit portion 30 is accommodated in the inverter accommodating portion 7 in a state where the second case member 39 faces the bottom side of the inverter accommodating portion 7. The bolts 16 that have been inserted sequentially through the fourth mounting holes 371 of the first case member 37, the first mounting holes 317 of the first filter circuit board 31, the third mounting holes 357 of the bus bar member 35, the second mounting holes 337 of the second filter circuit board 33, and the fifth mounting holes 393 of the second case member 39 are screwed into threaded holes formed in the filter attachment portion 17. Consequently, the first filter circuit board 31, the second filter circuit board 33, the bus bar member 35, the first case member 37, and the second case member 39 are integrally fixed in the inverter accommodating portion 7.

When the installation of the inverter circuit portion 20 and the filter circuit portion 30 in the inverter accommodating portion 7 is completed, the cover member 8 is fixed to the peripheral wall 73 of the inverter accommodating portion 7.

Here, in the embodiment, when the filter circuit portion 30 is accommodated in the inverter accommodating portion 7, a sheet-like first antivibration member 18 is installed on the bottom portion of the inverter accommodating portion 7, or the first antivibration member 18 is attached to an outer surface of the second case member 39. Moreover, when the filter circuit portion 30 is accommodated in the inverter accommodating portion 7, a sheet-like second antivibration member 19 is attached to an outer surface of the first case member 37, or when the cover member 8 is fixed to the peripheral wall of the inverter accommodating portion 7, the second antivibration member 19 is attached to the outer surface of the first case member 37 or an inner surface of the cover member 8. Consequently, in addition to being attached and fixed to the filter attachment portion 17 with the bolts 16, the filter circuit portion 30 is held between the bottom portion of the inverter accommodating portion 7 and the cover member 8 in a state where the first antivibration member 18 is placed between the second case member 39 and the bottom portion of the inverter accommodating portion 7 and the second antivibration member 19 is placed between the first case member 37 and the cover member 8.

The electric compressor 1 according to the embodiment has, for example, the following effects:

In the electric compressor 1 according to the embodiment, the filter circuit portion 30 for reducing electromagnetic noise includes the first filter circuit board 31 on which the plurality of electrolytic capacitors 51 as the at least one first filter component is mounted, the second filter circuit board 33 on which the normal mode choke coil 53, the common mode choke coil 55 and the like as the at least one second filter component are mounted, and the bus bar member 35 having the pair of bus bars 351 and 351 and the resin holding portion 352 for holding the pair of bus bars 351 and 351. In addition, the first filter circuit board 31, the second filter circuit board 33, and the bus bar member 35 are accommodated in the inverter accommodating portion 7 in the state where the first filter circuit board 31 and the second filter circuit board 33 are placed on top of each other across the bus bar member 35.

In other words, in the embodiment, a plurality of filter components (the electrolytic capacitors 51, and the normal mode choke coil 53, the common mode choke coil 55 and the like) for electromagnetic noise suppression is mounted in a distributed manner on two circuit boards (the first filter circuit board 31 and the second filter circuit board 33), and the two circuit boards (the first filter circuit board 31 and the second filter circuit board 33) can be placed, for example, vertically across the bus bar member 35 in the inverter accommodating portion 7. Hence, even if the filter components increase in size or the number of filter components increases, increases in the projected areas of the filter circuit boards forming the filter circuit portion 30, and by extension an increase in the projected area of the inverter accommodating portion 7, are suppressed. Therefore, the limitation of the place where the electric compressor 1 is installed and an increase in noise caused by the vibration of the cover member 8 are also suppressed. Moreover, the electrolytic capacitors 51, and the normal mode choke coil 53 and the common mode choke coil 55, which generate a large amount of heat, are mounted on the different circuit boards. Therefore, thermal interference therebetween is suppressed.

In particular, in the embodiment, the plurality of electrolytic capacitors 51 is mounted on the one surface of the first filter circuit board 31, and the normal mode choke coil 53, the common mode choke coil 55 and the like are mounted on the one surface of the second filter circuit board 33. The bus bar member 35 is formed as the plate-shaped resin molded body in which the pair of bus bars 351 and 351 has been inserted. In addition, the first filter circuit board 31, the second filter circuit board 33, and the bus bar member 35 are accommodated in the inverter accommodating portion 7 in the state where the other surface of the first filter circuit board 31 and the other surface of the second filter circuit board 33 are placed in such a manner as to face each other across the bus bar member 35. Hence, the first filter circuit board 31 and the second filter circuit board 33 are reinforced by the bus bar member 35, and the vibration resistance of the filter circuit board, and by extension the filter circuit portion 30, is improved. Moreover, (the holding portion 352 of) the bus bar member 35 functions as an insulating wall between the first filter circuit board 31 and the second filter circuit board 33, and an insulation distance between the first filter circuit board 31 and the second filter circuit board 33 is also secured.

Moreover, the first filter circuit board 31 is fixed by thermal staking to the one surface of the bus bar member 35, and the second filter circuit board 33 is fixed by thermal staking to the other surface of the bus bar member 35. Hence, the first filter circuit board 31, the second filter circuit board 33, and the bus bar member 35 can be integrated (modularized) without using an additional component such as a bolt, and reductions in assemblability of the filter circuit portion 30 and assemblability of the filter circuit portion 30 to the inverter accommodating portion 7 due to distributed mounting of the filter components on the two circuit boards are suppressed.

Moreover, the filter circuit portion 30 includes the first case member 37 that is placed on the one surface of the first filter circuit board 31 and accommodates the plurality of electrolytic capacitors 51, and the second case member 39 that is placed on the one surface of the second filter circuit board 33 and accommodates the normal mode choke coil 53, the common mode choke coil 55 and the like In other words, the first case member 37 can protect the plurality of electrolytic capacitors 51 against vibration, and the second case member 39 can protect the normal mode choke coil 53, the common mode choke coil 55 and the like against vibration. Hence, the vibration resistance of the filter circuit portion 30 is improved. In particular, in the embodiment, the gaps in the first case member 37 and the gaps in the second case member 39 are filled with resin. Hence, the vibration resistance of the filter circuit portion 30 is further improved, and the first case member 37 and the second case member 39, in addition to the first filter circuit board 31, the second filter circuit board 33, and the bus bar member 35, can also be integrated (modularized), and the assemblability of the filter circuit portion 30 to the inverter accommodating portion 7 is improved.

Moreover, each of the first filter circuit board 31, the second filter circuit board 33, the bus bar member 35, the first case member 37, and the second case member 39 is formed with the bolt insertion holes (317, 337, 357, 371, 393) through which the bolts for integrally fixing the first filter circuit board 31, the second filter circuit board 33, the bus bar member 35, the first case member 37, and the second case member 39 in the inverter accommodating portion 7 are inserted. Hence, the filter circuit portion 30 is easily and firmly fixed in the inverter accommodating portion 7, and high vibration resistance can be obtained.

Moreover, the filter circuit portion 30 is held between the bottom portion of the inverter accommodating portion 7 and the cover member 8 in the state where the first antivibration member 18 is placed between the second case member 39 and the bottom portion of the inverter accommodating portion 7, and the second antivibration member 19 is placed between the first case member 37 and the cover member 8. Hence, the filter circuit portion 30 is more firmly fixed in the inverter accommodating portion 7, and higher vibration resistance can be obtained.

Moreover, each of the two surfaces of the bus bar member 35 is formed with the inner portion 352b that is recessed relative to the peripheral edge portion 352a. The electronic components smaller than the plurality of electrolytic capacitors 51 are mounted on the other surface of the first filter circuit board 31, and the electronic components smaller than the normal mode choke coil 53, the common mode choke coil 55 and the like are mounted on the other surface of the second filter circuit board 33. Hence, increases in the projected areas of the filter circuit boards configuring the filter circuit portion 30, and by extension an increase in the projected area of the inverter accommodating portion 7, are further effectively suppressed. Moreover, for example, interference with the small electronic components such as the plurality of electrolytic capacitors 51, and the normal mode choke coil 53, the common mode choke coil 55 and the like is also suppressed.

Note that in the above-mentioned embodiment, the housing 5 and the inverter accommodating portion 7 are integrally formed. However, the embodiment is not limited to the above. The inverter accommodating portion 7 is simply required to be provided integrally with the housing 5, and for example, the housing 5 and the inverter accommodating portion 7 may be formed separately, and then assembled and integrated.

Moreover, in the above-mentioned embodiment, the plurality of electrolytic capacitors 51 is mounted on the one surface of the first filter circuit board 31, and the normal mode choke coil 53, the common mode choke coil 55 and the like are mounted on the one surface of the second filter circuit board 33. However, the embodiment is not limited to the above. The plurality of filter components for electromagnetic noise suppression is simply required to be mounted in a distributed manner on the first filter circuit board 31 and the second filter circuit board 33. Moreover, in contrast to the above-mentioned embodiment, the normal mode choke coil 53, the common mode choke coil 55 and the like may be mounted on the one surface of the first filter circuit board 31, and the plurality of electrolytic capacitors 51 may be mounted on the one surface of the second filter circuit board 33.

Moreover, in the above-mentioned embodiment, the filter circuit portion 30 is held between the bottom portion of the inverter accommodating portion 7 and the cover member 8 in the state where the antivibration members are placed between the second case member 39 and the bottom portion of the inverter accommodating portion 7 and between the first case member 37 and the cover member 8, respectively. However, the embodiment is not limited to the above. The filter circuit portion 30 may be held between the bottom portion of the inverter accommodating portion 7 and the cover member 8 in a state where the antivibration member is placed at least one of between the second case member 39 and the bottom portion of the inverter accommodating portion 7 or between the first case member 37 and the cover member 8.

Moreover, the bus bar member 35 may further include a metal shielding plate 41 placed in the holding portion 352. The shielding plate 41 blocks electromagnetic noise, and, for example, is formed in such a manner as to have an outer shape substantially corresponding to the inner portions 352b of the holding portion 352 as indicated by a broken line in FIG. 6. The shielding plate 41, together with the pair of bus bars 351 and 351, is then inserted at the time of molding the bus bar member 35. In other words, the bus bar member 35 can be formed as a plate-shaped resin molded body in which the pair of bus bars 351 and 351 and the shielding plate 41 have been inserted. As a result, for example, a malfunction accompanied by interference of radiated noise between the first filter circuit board 31 and the second filter circuit board 33 can be effectively prevented.

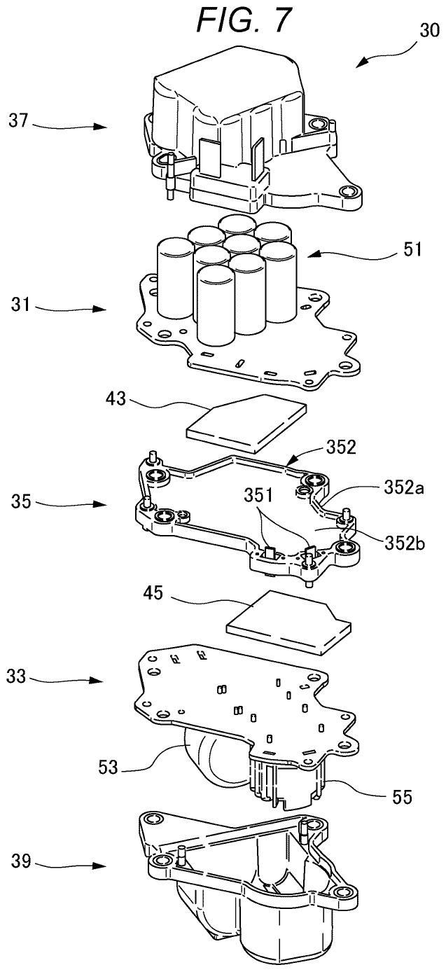

Furthermore, as illustrated in FIG. 7, a sheet-like second heat dissipation member 43 may be placed between the first filter circuit board 31 and the bus bar member 35, and a sheet-like third heat dissipation member 45 may be placed between the second filter circuit board 33 and the bus bar member 35. In this case, it is preferable that the second heat dissipation member 43 be placed in the inner portion 352b on the one surface side of the holding portion 352 of the bus bar member 35 in such a manner as to be located below the plurality of electrolytic capacitors 51, and the third heat dissipation member 45 be placed in the inner portion 352b on the other surface side of the holding portion 352 of the bus bar member 35 in such a manner as to be located above the normal mode choke coil 53, the common mode choke coil 55 and the like. In this manner, the heat produced by the electrolytic capacitors 51 and the heat produced by the normal mode choke coil 53, the common mode choke coil 55 and the like can be efficiently dissipated.

Up to this point the embodiment of the present invention and its modifications have been described. However, the present invention is not limited to the above-mentioned embodiment and modifications, and as a matter of course, the present invention can be modified further on the basis of the technical idea of the present invention.

### LIST OF REFERENCE SIGNS

1 Electric Compressor
2 Rotary shaft
3 Motor
4 Compression mechanism
5 Housing
6 Inverter
7 Inverter accommodating portion
8 Cover member
18 First antivibration member
19 Second antivibration member
20 Inverter circuit portion
21 Power switching element
23 Control circuit
25 Inverter control board
30 Filter circuit portion
31 First filter circuit board
33 Second filter circuit board
35 Bus bar member
37 First case member
39 Second case member
51 Electrolytic capacitor
53 Normal mode choke coil
55 Common mode choke coil
317 First mounting hole
337 Second mounting hole
351 Bus bar
352 Holding portion
352a Peripheral edge portion
352b Inner portion
357 Third mounting hole
371 Fourth mounting hole
393 Fifth mounting hole
R Resin

1. An electric compressor comprising:
a housing configured to accommodate a motor that rotates a rotary shaft and a compression mechanism that is driven by rotation of the rotary shaft;
an inverter accommodating portion that is provided integrally with the housing, includes an opening portion, and is configured to accommodate an inverter that drives the motor; and
a cover member configured to block the opening portion of the inverter accommodating portion, wherein
the inverter includes an inverter circuit portion that supplies power to the motor, and a filter circuit portion for reducing electromagnetic noise,
the filter circuit portion includes a first filter circuit board on which at least one first filter component is mounted, a second filter circuit board on which at least one second filter component is mounted, and a bus bar member having a bus bar that electrically connects the first filter circuit board and the second filter circuit board, and a resin holding portion that holds the bus bar, and
the first filter circuit board, the second filter circuit board, and the bus bar member are accommodated in the inverter accommodating portion in a state where the first filter circuit board and the second filter circuit board are placed on top of each other across the bus bar member.

2. The electric compressor according to claim 1, wherein
the at least one first filter component is mounted on one surface of the first filter circuit board, the at least one second filter component is mounted on one surface of the second filter circuit board, and the bus bar member is formed as a plate-shaped resin molded body in which the bus bar has been inserted, and
the first filter circuit board, the second filter circuit board, and the bus bar member are accommodated in the inverter accommodating portion in a state where the other surface of the first filter circuit board and the other surface of the second filter circuit board are placed, facing each other across the bus bar member.

3. The electric compressor according to claim 2, wherein the first filter circuit board is fixed by thermal staking to one surface of the bus bar member, and the second filter circuit board is fixed by thermal staking to the other surface of the bus bar member.

4. The electric compressor according to claim 2, wherein the filter circuit portion further includes: a first case member that is placed on the one surface of the first filter circuit board and accommodates the at least one first filter component; and a second case member that is placed on the one surface of the second filter circuit board and accommodates the at least one second filter component.

5. The electric compressor according to claim 4, wherein a gap in the first case member and a gap in the second case member are filled with resin.

6. The electric compressor according to claim 4, wherein each of the first filter circuit board, the second filter circuit board, the bus bar member, the first case member, and the second case member is formed with a bolt insertion hole through which a bolt for integrally fixing the first filter circuit board, the second filter circuit board, the bus bar member, the first case member, and the second case member in the inverter accommodating portion is inserted.

7. The electric compressor according to claim 4, wherein the filter circuit portion is held between a bottom portion of the inverter accommodating portion and the cover member in a state where an antivibration member is placed at least one of between the second case member and the bottom portion of the inverter accommodating portion or between the first case member and the cover member.

8. The electric compressor according to claim 2, wherein
each of two surfaces of the bus bar member is formed with an inner portion that is recessed relative to a peripheral edge portion, and
an electronic component smaller than the at least one first filter component is mounted on the other surface of the first filter circuit board, and an electronic component smaller than the at least one second filter component is mounted on the other surface of the second filter circuit board.

9. The electric compressor according to claim 1, wherein
one of the at least one first filter component or the at least one second filter component includes a plurality of electrolytic capacitors, and the other of the at least one first filter component or the at least one second filter component includes a normal mode choke coil and a common mode choke coil.

10. The electric compressor according to claim 2, wherein
one of the at least one first filter component or the at least one second filter component includes a plurality of electrolytic capacitors, and the other of the at least one first filter component or the at least one second filter component includes a normal mode choke coil and a common mode choke coil.

11. The electric compressor according to claim 3, wherein
one of the at least one first filter component or the at least one second filter component includes a plurality of electrolytic capacitors, and the other of the at least one first filter component or the at least one second filter component includes a normal mode choke coil and a common mode choke coil.

12. The electric compressor according to claim 4, wherein
one of the at least one first filter component or the at least one second filter component includes a plurality of electrolytic capacitors, and the other of the at least one first filter component or the at least one second filter component includes a normal mode choke coil and a common mode choke coil.

13. The electric compressor according to claim 5, wherein
one of the at least one first filter component or the at least one second filter component includes a plurality of electrolytic capacitors, and the other of the at least one first filter component or the at least one second filter component includes a normal mode choke coil and a common mode choke coil.

14. The electric compressor according to claim 6, wherein
one of the at least one first filter component or the at least one second filter component includes a plurality of electrolytic capacitors, and the other of the at least one first filter component or the at least one second filter component includes a normal mode choke coil and a common mode choke coil.

15. The electric compressor according to claim 7, wherein
one of the at least one first filter component or the at least one second filter component includes a plurality of electrolytic capacitors, and the other of the at least one first filter component or the at least one second filter component includes a normal mode choke coil and a common mode choke coil.

16. The electric compressor according to claim 8, wherein
one of the at least one first filter component or the at least one second filter component includes a plurality of electrolytic capacitors, and the other of the at least one first filter component or the at least one second filter component includes a normal mode choke coil and a common mode choke coil.
